(19) United States
(12) Patent Application Publication
(10) Pub. No.: US 2023/0164932 A1
(43) Pub. Date: May 25, 2023

(54) HOUSING ELEMENT, COMBINATION OF A PRESSURE COMPENSATION ELEMENT AND A HOUSING ELEMENT, AND METHOD FOR PRODUCING SUCH A COMBINATION

(71) Applicant: ELRINGKLINGER AG, Dettingen (DE)

(72) Inventors: Björn Betz, Trochtelfingen (DE); Tobias Kunert, Reutlingen (DE); Thilo Lutz, Stuttgart (DE); Jochen Schöllhammer, Dettingen (DE); Tobias Zimmermann, Usingen (DE)

(21) Appl. No.: 18/156,922

(22) Filed: Jan. 19, 2023

Related U.S. Application Data
(63) Continuation of application No. PCT/EP2021/069468, filed on Jul. 13, 2021.

(30) Foreign Application Priority Data
Jul. 21, 2020 (DE) 10 2020 119 211.8

(51) Int. Cl. H05K 5/02

(52) U.S. Cl. CPC H05K 5/0215

(57) ABSTRACT

In order to create a housing element, comprising a housing wall and a receiving structure for a pressure compensation element, wherein the receiving structure comprises a through-opening for the passage of a gas, said housing element being configured such that a collection of liquid on a pressure compensation element mounted on the housing element is prevented or at least reduced, it is proposed that the receiving structure comprises at least one pressure compensation element abutment face that is raised, at least in sections, relative to an outer face of a base region of the housing wall.

### RELATED APPLICATIONS

This application is a continuation of international application number PCT/EP2021/069468 filed on 13 Jul. 2021 and claims the benefit of German application number 10 2020 119 211.8 filed on 21 Jul. 2020.

The present disclosure relates to the subject matter disclosed in international application number PCT/EP2021/069468 of 13 Jul. 2021 and German application number 10 2020 119 211.8 of 21 Jul. 2020, which are incorporated herein by reference in their entirety and for all purposes.

### FIELD OF THE DISCLOSURE

The present invention relates to a housing element, which comprises a housing wall and a receiving structure for a pressure compensation element, wherein the receiving structure comprises a through-opening for the passage of a gas.

Such a housing element serves to close an opening in a housing that comprises at least one further housing part, for example a housing body, in addition to the housing element.

By means of the pressure compensation element that is insertable into the housing element, it is possible to produce a pressure compensation between an inside space enclosed by the housing and an outside space of the housing.

In known housing elements of the aforementioned kind, there is the problem that liquid collects on the pressure compensation element mounted on the housing element and may impair the function of the pressure compensation element.

In accordance with an embodiment of the invention, a housing element of the kind stated at the outset is created, which is configured such that the collection of liquid on a pressure compensation element mounted on the housing element is prevented or at least reduced.

### SUMMARY OF THE INVENTION

In accordance with an embodiment of the invention, provision is made in a housing element with the features of the preamble of claim 1 that the receiving structure comprises at least one pressure compensation element abutment face that is raised, at least in sections, relative to an outer face of a base region of the housing wall.

Underlying the present invention is the concept of reducing or completely preventing the collection of liquid on a pressure compensation element mounted on the housing element by the pressure compensation element being arranged on a pressure compensation element abutment face that is arranged raised relative to an outer face of a base region of the housing wall of the housing element.

In contrast to the arrangement of the pressure compensation element on a pressure compensation element abutment face that is arranged at the same level as the outer face of the base region or even at a lower level than the outer face of the base region, the collection of liquid on the pressure compensation element is hereby reduced or completely prevented and the discharge of liquid from the pressure compensation element onto the base region of the housing wall of the housing element is promoted.

Each point of the pressure compensation element abutment face has an offset V along a thickness direction of the base region of the housing wall relative to the outer face of the base region of the housing wall.

Seen from the outer face of the base region of the housing wall, this offset V is directed outwardly, i.e., toward the outside space side of the housing element.

In a preferred embodiment of the invention, provision is made that the receiving structure comprises a raised web extending around the pressure compensation element abutment face.

Such a raised web is preferably provided with at least one discharge opening.

It is particularly favorable if the web is provided with two or more discharge openings, in particular with three or more discharge openings, particularly preferably with four or more discharge openings.

Each discharge opening may be configured, e.g., as a recess that opens at an upper rim of the web.

Here, the upper rim of the web is a rim of the web that points away from the outer face of the base region of the housing wall of the housing element.

It is particularly favorable for the discharge of liquid from the pressure compensation element if the pressure compensation element abutment face is inclined, at least in sections, relative to the outer face of the base region of the housing wall.

The pressure compensation element abutment face is preferably inclined as a whole relative to the outer face of the base region of the housing wall.

The angle of inclination α by which the pressure compensation element abutment face is inclined relative to the outer face of the base region of the housing wall is preferably smaller than 30°, in particular smaller than 10°, particularly preferably smaller than 5°.

Furthermore, provision is preferably made that the angle of inclination α is greater than 1°, particularly preferably greater than 2°.

In a particular embodiment of the invention, provision is made that the receiving structure of the housing element comprises two partial pressure compensation element abutment faces that are inclined relative to the outer face of the base region of the housing wall and have mutually different slope directions.

Adjoining partial pressure compensation element abutment faces together form a pressure compensation element abutment face of the receiving structure.

Here, provision may be made, for example, that at least two of the partial pressure compensation element abutment faces of the receiving structure adjoin one another along a crest line and slope down from the crest line along mutually different slope directions.

Here, the crest line preferably runs through the longitudinal central axis of the through-opening of the receiving structure.

For example, a first partial pressure compensation element abutment face slopes down from this crest line along a first slope direction up to a first lowest point of the pressure compensation element abutment face, while a second partial pressure compensation element abutment face slopes down from the crest line along a second slope direction oriented opposite to the first slope direction up to a second lowest point of the pressure compensation element abutment face.

In this case, liquid from the pressure compensation that is mounted on the housing element can discharge from the pressure compensation element in two opposite slope directions.

The receiving structure is preferably formed in one piece with the housing wall, in particular in one piece with the base region of the housing wall.

The receiving structure is preferably formed by reshaping part of the housing wall.

The reshaping operation by which the receiving structure is formed from part of the housing wall may comprise, in particular, an embossing operation, a bending operation, or a deep-drawing operation.

The minimum offset Vₘᵢₙ by which the lowest part of the pressure compensation element abutment face is offset outwardly in the thickness direction of the base region relative to the outer face of the base region of the housing wall may be smaller than the material thickness d of the housing wall in the base region of the housing wall.

In an alternative embodiment of the invention, provision may be made that the minimum offset Vₘᵢₙ by which the lowest point of the pressure compensation element abutment face is offset outwardly in the thickness direction of the base region relative to the abutment face of the base region of the housing wall is greater than the material thickness d of the housing wall in the base region.

Furthermore, provision may be made that the minimum offset Vₘᵢₙ by which the lowest point of the pressure compensation element abutment face is offset outwardly relative to the outer face of the base region of the housing wall is substantially equal to the material thickness d of the housing wall in the base region of the housing wall.

The housing element in accordance with the invention is suited, in particular, for use in a combination that comprises a pressure compensation element and a housing element in accordance with the invention, wherein the pressure compensation element is preferably arranged on the receiving structure of the housing element.

The pressure compensation element preferably comprises a pressure compensation membrane, which is arranged on the pressure compensation element abutment face of the housing element.

The pressure compensation element membrane may be configured as a semipermeable membrane.

The pressure compensation element membrane may be configured as a film.

The pressure compensation element membrane is preferably connected to the pressure compensation element abutment face by substance-to-substance bond.

In particular, provision may be made that the pressure compensation element membrane is adhesively bonded to the pressure compensation element abutment face.

In a preferred embodiment of the invention, provision is made that the pressure compensation element comprises a protective cap, which covers the pressure compensation element membrane.

The protective cap preferably consists of a metallic material, for example a steel material or an aluminum material.

Such a protective cap may comprise at least one ventilation channel.

Provision is preferably made that the protective cap comprises two or more ventilation channels, in particular three or more ventilation channels, particularly preferably four or more ventilation channels.

Each ventilation channel preferably extends from an outside space-side fluid receiving space of the pressure compensation element up to an outlet opening of the respective ventilation channel.

The outside space-side fluid receiving space is preferably arranged on the pressure compensation element membrane located opposite the through-opening of the receiving structure of the housing element.

The outside space-side fluid receiving space of the pressure compensation element is preferably arranged substantially centrally on the pressure compensation element.

The at least one ventilation channel preferably extends from the outside space-side fluid receiving space of the pressure compensation element, for example in the radial direction, up to the outer periphery of the pressure compensation element.

A plurality of ventilation channels of the protective cap, which are in alignment with one another in their longitudinal direction, may together form a longer rectilinear ventilation channel.

In a particular embodiment of the invention, provision is made that the protective cap comprises two intersecting ventilation channels.

The ventilation channels may, in particular, intersect in the region of an outside space-side fluid receiving space of the pressure compensation element

In particular embodiments of the invention, provision is made that the protective cap comprises a collar, which laterally covers a rim of the pressure compensation element membrane.

In this way, in particular, a rim of the pressure compensation element membrane on the peripheral side can be protected from environmental influences.

The protective cap of the pressure compensation element may, in particular, be connected to the pressure compensation element membrane of the pressure compensation element by substance-to-substance bond.

In particular, provision may be made that the protective cap is adhesively bonded to the pressure compensation element membrane.

For example, provision may be made that, preferably substantially planar, regions of the protective cap that are located outside of the ventilation channel or ventilation channels of the protective cap are connected to the pressure compensation element membrane by substance-to-substance bond, particularly preferably adhesively bonded to the pressure compensation element membrane.

The present invention further relates to a method for producing a combination of a housing element and a pressure compensation element.

In accordance with an embodiment of the invention, such a method is created, by means of which a combination of a housing element and a pressure compensation element is produced in which a collection of liquid on the pressure compensation element is reduced or completely prevented.

In accordance with an embodiment of the invention, a method for producing a combination of a housing element and a pressure compensation element is provided, wherein the method comprises the following:
reshaping a housing wall of the housing element for forming a receiving structure;
producing a through-opening in the region of the receiving structure, wherein the receiving structure comprises at least one pressure compensation element abutment face that is raised, at least in sections, relative to an outer face of a base region of the housing wall;
arranging a pressure compensation element membrane of the pressure compensation element on the at least one pressure compensation element abutment face.

In a particular embodiment of this method in accordance with the invention, provision is made that a protective cap is arranged on the side of the pressure compensation element membrane of the pressure compensation element that faces away from the receiving structure of the housing element.

Further preferred embodiments of such a method for producing a combination of a housing element and a pressure compensation element have already been described above in connection with particular embodiments of the housing element in accordance with the invention and particular embodiments of the combination in accordance with the invention of a pressure compensation element and a housing element.

The method in accordance with the invention is suited, in particular, for producing the combination in accordance with the invention of a housing element and a pressure compensation element.

In a particular embodiment of the claimed invention, a housing element is produced by a reshaping operation and is provided with a connection geometry or receiving structure for a pressure compensation element.

The pressure compensation element may, in particular, be adhesively bonded onto the receiving structure of the housing element.

By arranging the pressure compensation element on a pressure compensation element abutment face that is raised relative to an outer face of a base region of a housing wall of the housing element, a collection of liquid on the pressure compensation element can be reduced or completely prevented, thereby avoiding an impairment to the function of the pressure compensation element.

The pressure compensation element abutment face is preferably oriented, at least in sections, obliquely to the outer face of the base region of the housing wall of the housing element.

It is thereby made possible that liquid that has collected on the pressure compensation element discharges from the pressure compensation element along the slope direction of the pressure compensation element abutment face that is sloped at least in sections.

The raised pressure compensation element abutment face is preferably produced by a reshaping operation, for example an embossing operation, a bending operation, or a deep-drawing operation.

The pressure compensation element abutment face may comprise one partial pressure compensation element abutment face oriented obliquely to the outer face of the base region of the housing wall of the housing element or two or more partial pressure compensation element abutment faces oriented obliquely to the outer face of the base region of the housing wall.

The pressure compensation element abutment face may be surrounded by a web, which preferably protects a peripheral face of a pressure compensation element membrane of the pressure compensation element.

This web may comprise a discharge opening at one or more locations, through which liquid from the pressure compensation element can flow onto the outer face of the base region of the housing wall of the housing element.

The receiving structure of the housing element is preferably surrounded by the base region of the housing wall of the housing element.

Provision is preferably made that the base region of the housing wall of the housing element directly adjoins the receiving structure of the housing element.

The outer face of the base region of the housing wall of the housing element is preferably of substantially planar configuration.

The pressure compensation element may comprise a protective cap.

The protective cap may be connected to a pressure compensation element membrane of the pressure compensation element and/or to the receiving structure of the housing element by substance-to-substance bond.

In a preferred embodiment of the invention, provision is made that the protective cap is connected to the pressure compensation element membrane of the pressure compensation element and/or to the receiving structure of the housing element by adhesion.

The protective cap may comprise one or more ventilation channels, which serve to and/or aerate and/or ventilate the protective cap or the pressure compensation element.

Such a ventilation channel may be configured, e.g., as a bead.

The protective cap may comprise a collar, which projects beyond a peripheral rim of a pressure compensation element membrane of the pressure compensation element, in order to protect said peripheral rim of the pressure compensation element membrane.

Such a collar may be formed, in particular, by a reshaping operation, for example by an embossing operation, a bending operation, or a deep-drawing operation on the protective cap.

The housing element may be configured, in particular, as a housing cover.

The protective cap may comprise a metallic material. The protective cap is preferably made of a metallic material.

If the minimum offset Vₘᵢₙ of the pressure compensation element abutment face of the receiving structure of the housing element relative to the outer face of the base region of the housing wall of the housing element is smaller than the material thickness d of the housing wall in the base region, the receiving structure is preferably produced by an embossing operation.

If the minimum offset Vₘᵢₙ of the pressure compensation element abutment face of the receiving structure of the housing element relative to the outer face of the base region of the housing wall of the housing element is equal to or greater than the material thickness d of the housing wall in the base region, the receiving structure is preferably produced by a bending operation or a deep-drawing operation.

Further features and advantages of the invention are subject matter of the subsequent description and the graphical representation of exemplary embodiments.

### BRIEF DESCRIPTION OF THE DRAWINGS

FIG. 1 shows a perspective depiction of a combination of a housing element and a pressure compensation element, wherein the housing element comprises a housing wall and a receiving structure for the pressure compensation element, wherein the receiving structure comprises a through-opening for the passage of a gas and at least one pressure compensation element abutment face that is raised relative to an outer face of a base region of the housing wall, with the viewing direction toward the outside space side of the housing element;

FIG. 2 shows a plan view of the combination of the housing element and the pressure compensation element from FIG. 1, with a view to the outside space side of the housing element;

FIG. 3 shows a perspective exploded depiction of the combination of the housing element and the pressure compensation element from FIGS. 1 and 2, wherein the housing element, a pressure compensation element membrane of the pressure compensation element, and a protective cap of the pressure compensation element are depicted spaced at a distance from one another along a longitudinal central axis of the receiving structure;

FIG. 4 shows a sectional longitudinal cut through of the combination of the housing element and the pressure compensation element from FIGS. 1 to 3, along line 4-4 in FIG. 2;

FIG. 5 shows a perspective depiction of the pressure compensation element from FIGS. 1 to 4, with the viewing direction toward a bottom side of the pressure compensation element membrane of the pressure compensation element that faces away from the protective cap of the pressure compensation element;

FIG. 6 shows a perspective depiction of the protective cap of the pressure compensation element from FIG. 5, with the viewing direction toward a bottom side of the protective cap that faces toward the pressure compensation element membrane in the mounted state of the pressure compensation element;

FIG. 7 shows a perspective depiction of the housing element from FIGS. 1 to 4, with the viewing direction toward an outside space side of the housing element;

FIG. 8 shows a perspective depiction of a second embodiment of a combination of a housing element and a pressure compensation element, wherein the protective cap of the pressure compensation element comprises a collar, which laterally covers a peripheral rim of the pressure compensation element membrane;

FIG. 9 shows a plan view of the combination of the housing element and the pressure compensation element from FIG. 8, with the viewing direction toward the outside space side of the housing element;

FIG. 10 shows a perspective exploded depiction of the combination of a housing element and a pressure compensation element from FIGS. 8 and 9, wherein the housing element, a pressure compensation element membrane of the pressure compensation element, and the protective cap of the pressure compensation element are depicted spaced at a distance from one another along a longitudinal central axis of the receiving structure for the pressure compensation element;

FIG. 11 shows a sectional longitudinal cut through of the combination of the housing element and the pressure compensation element from FIGS. 8 to 10, along line 11-11 in FIG. 9;

FIG. 12 shows a perspective depiction of the pressure compensation element from FIGS. 8 to 11, with the viewing direction toward a bottom side of the pressure compensation element that faces toward the receiving structure of the housing element in the mounted state of the pressure compensation element;

FIG. 13 shows a perspective depiction of the protective cap of the pressure compensation element from FIGS. 8 to 12, with the viewing direction toward a bottom side of the protective cap that faces toward the pressure compensation element membrane in the mounted state of the pressure compensation element;

FIG. 14 shows a perspective depiction of the housing element from FIGS. 8 to 11, with the viewing direction toward the outside space side of the housing element;

FIG. 15 shows a sectional longitudinal cut corresponding to FIG. 4 through a third embodiment of a combination of a housing element and a pressure compensation element, wherein the protective cap of the pressure compensation element comprises a collar, which laterally covers a rim of the pressure compensation element membrane, and wherein the pressure compensation element abutment face of the receiving structure of the housing element is oriented substantially in parallel to an outer face of a base region of the housing wall;

FIG. 16 shows a sectional longitudinal cut corresponding to FIG. 4 through a fourth embodiment of a combination of a housing element and a pressure compensation element, wherein a protective cap of the pressure compensation element comprises a collar, which laterally covers a rim of a pressure compensation element membrane of the pressure compensation element, and wherein the receiving structure comprises two partial compensation element abutment faces that are inclined relative to an outer face of a base region of the housing wall of the housing element, said partial pressure compensation element abutment faces having mutually different slope directions;

FIG. 17 shows a sectional longitudinal cut corresponding to FIG. 15 through a fifth embodiment of a combination of a housing element and a pressure compensation element, wherein the housing wall of the housing element has a smaller material thickness d than in the third embodiment depicted in FIG. 15;

FIG. 18 shows a sectional longitudinal cut corresponding to FIG. 16 through a sixth embodiment of a combination of a housing element and a pressure compensation element, wherein a housing wall of the housing element has a smaller material thickness d than in the fourth embodiment depicted in FIG. 16; and

FIG. 19 shows a sectional longitudinal cut corresponding to FIG. 4 through a seventh embodiment of a combination of a housing element and a pressure compensation element, wherein a housing wall of the housing element has a smaller material thickness d than in the first embodiment depicted in FIG. 4.

### DETAILED DESCRIPTION OF THE INVENTION

The same or functionally equivalent elements are provided with the same reference numerals in all Figures.

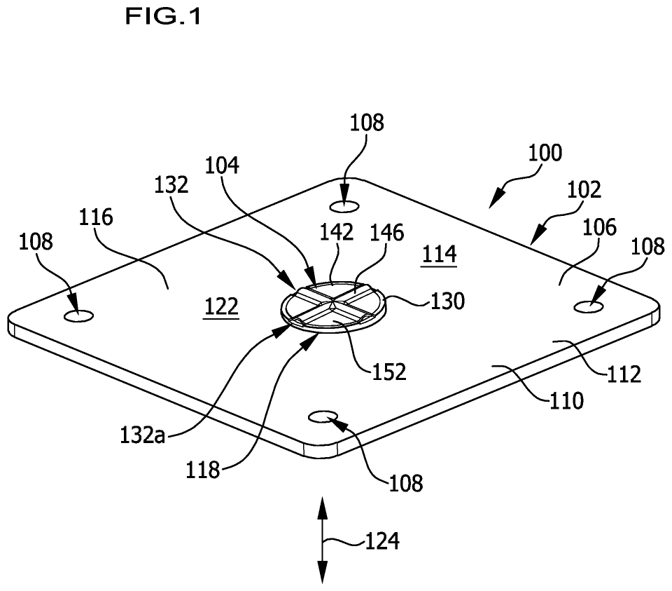

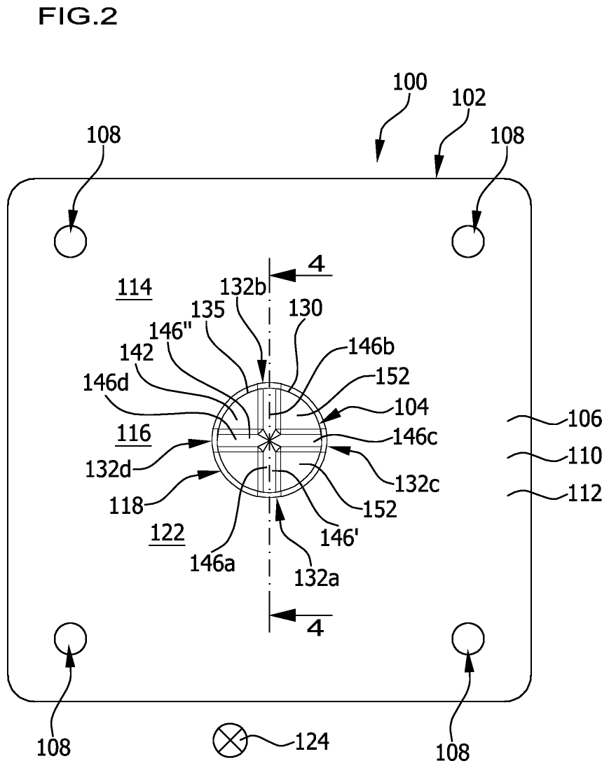

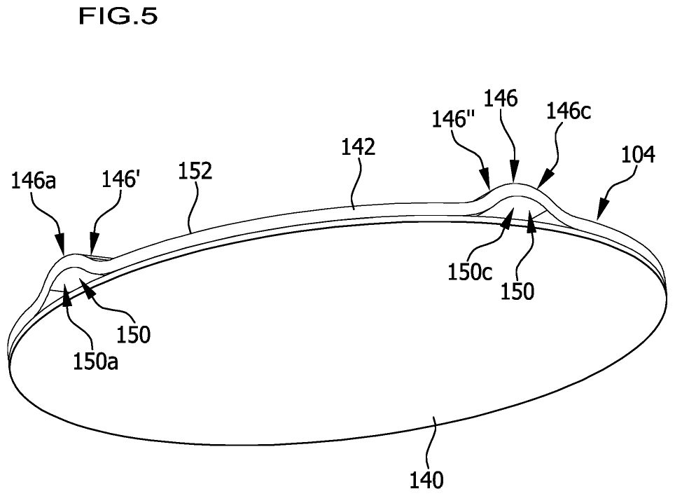

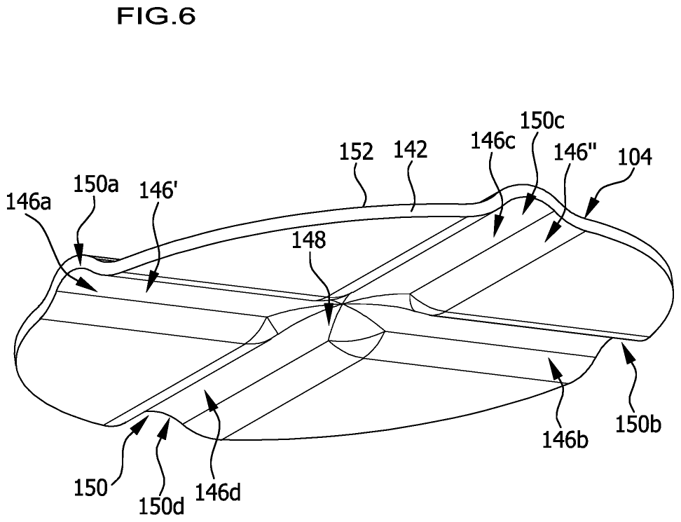

A combination, depicted in FIGS. 1 to 7 and denoted as a whole with 100, of a housing element 102 and a pressure compensation element 104 serves to close an opening in a housing (not depicted as a whole) by means of the housing element 102, said housing comprising at least one further housing part, for example a housing body, in addition to the depicted housing element 102, and to produce a pressure compensation between an inside space enclosed by the housing and an outside space of the housing by means of the pressure compensation element 104.

The housing element 102 is configured, e.g., as a housing cover 106.

The housing element 102 may comprise one or more fastening means through-openings 108 through which, in the assembled state of the housing, fastening means, for example screws, can extend in order to, preferably releasably, fix the housing element 102 to another housing part.

The housing element 102 comprises a housing wall 110 that is preferably configured, at least in sections, in the form of a plate 112.

The housing wall 110 preferably consists of a metallic material, for example a steel material or an aluminum material.

An aluminum material may be an aluminum alloy or substantially pure aluminum.

The housing wall 110 comprises an outer face 116 arranged on an outside space side 114 of the housing element 102, said outer face 116 preferably being of substantially planar configuration.

The housing element 102 further comprises a receiving structure 118 for accommodating the pressure compensation element 104.

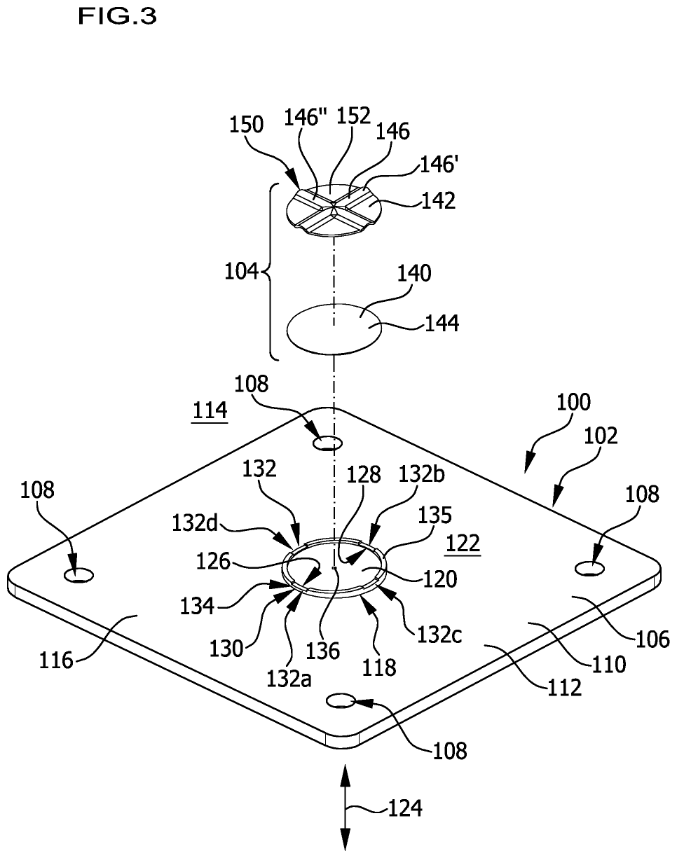

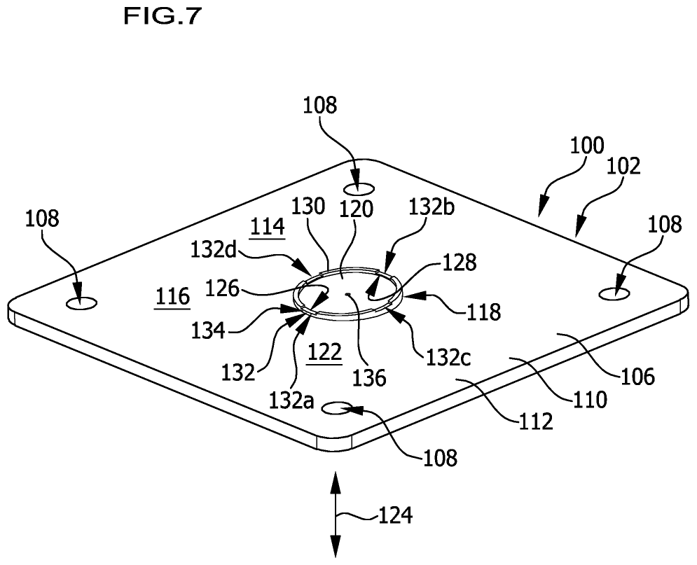

As can best be seen in FIGS. 3 and 7, the receiving structure 118 comprises a pressure compensation element abutment face 120, which is of raised configuration relative to the outer face 116 of the base region 112 of the housing wall 110 surrounding the receiving structure 118.

The pressure compensation element abutment face 120 is thus offset outwardly by an offset V along a thickness direction 124 of the base region 122 of the housing wall 110 relative to the outer face 116.

Furthermore, the pressure compensation element abutment face 120 is inclined by an angle α relative to the outer face 116 of the base region 122 of the housing wall 110.

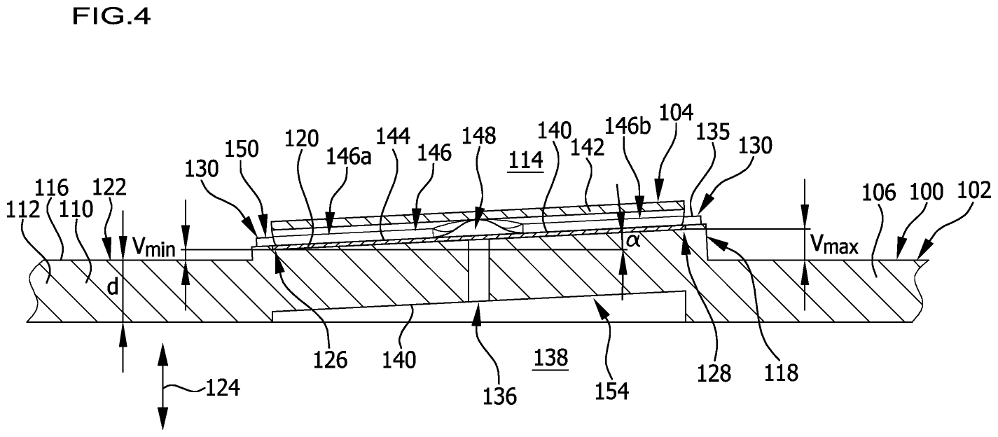

The offset Vₘᵢₙ outwards along the thickness direction 124 of the base region 122 relative to the outer face 116 of the base region 122 of the housing wall 110 is thus minimum at a point 126 of the pressure compensation element abutment face 120 depicted on the left in the sectional view of FIG. 4, while the offset Vₘₐₓ outwards along the thickness direction 124 of the base region 122 relative to the outer face 116 of the base region 122 of the housing wall 110 is maximum at a point 128 of the pressure compensation element abutment face 120 depicted on the right in FIG. 4.

In the first embodiment depicted in FIGS. 1 to 7, the minimum offset Vₘᵢₙ of the pressure compensation element abutment face 120 relative to the outer face 116 is smaller than the material thickness d of the housing wall 110 in the base region 122.

For example, provision may be made that Vₘᵢₙ is smaller than half, in particular smaller than a fourth, of the material thickness d of the housing wall 110 in the base region 122.

The maximum offset Vₘₐₓ of the pressure compensation element abutment face 120 relative to the outer face 116 is preferably also smaller than the material thickness d of the housing wall 110 in the base region 122.

Provision is preferably made that Vₘₐₓ is smaller than half, in particular smaller than a third, of the material thickness d of the housing wall 110 in the base region 122.

The angle of inclination α by which the pressure compensation element abutment face 120 is inclined relative to the substantially planar outer face 116 is preferably smaller than 30°, in particular smaller than 10°, particularly preferably smaller than 5°.

Furthermore, provision is preferably made that the angle of inclination α is greater than 1°, particularly preferably greater than 2°.

The receiving structure 118 for the pressure compensation element 104 further comprises a raised web 130 extending around the pressure compensation element abutment face 120.

As can best be seen in FIGS. 3 and 7, the web 130 is provided with at least one discharge opening 132.

The web 130 is preferably provided with two or more discharge openings 132, for example with at least three discharge openings 132, particularly preferably with at least four discharge openings 132.

Here, a discharge opening 132a is preferably arranged adjacent to the lowest point 126 of the pressure compensation element abutment face 120 at which the pressure compensation element abutment face 120 has the smallest offset Vₘᵢₙ relative to the outer face 116 of the base region 122 of the housing wall 110.

A discharge opening 132b is preferably arranged adjacent to the highest point 128 of the pressure compensation element abutment face 120 at which the pressure compensation element abutment face 120 has the greatest offset Vₘₐₓ relative to the outer face 116 of the base region 122 of the housing wall 110.

The two discharge openings 132a and 132b are preferably located diametrically opposed to one another.

Further discharge openings 132c and/or 132d may be arranged between the discharge openings 132a and 132b in the peripheral direction of the web 130.

In a preferred embodiment, provision is made that the discharge openings 132 are distributed substantially equidistantly along the periphery of the web 130.

The discharge openings 132 serve to allow liquid that has collected in the pressure compensation element 104 to discharge through the web 130 onto the outer face 116 of the base region 122 of the housing wall 110 of the housing element 102.

The discharge openings 132 may be configured, e.g., as recesses 134, which extend from an upper rim 135 of the web 130 in the direction toward the pressure compensation element abutment face 120.

As can best be seen in FIG. 4, the receiving structure 118 further comprises a through-opening 136, which extends from an inner face 140 of the receiving structure 118 that faces toward an inside space side 138 of the housing element 102 through the full material thickness of the housing wall 110 and opens at the pressure compensation element abutment face 120 of the receiving structure 118.

The passage opening 136 is preferably arranged substantially centrally on the pressure compensation element abutment face 120.

The passage opening 136 may extend in a direction substantially parallel to the thickness direction 124 of the base region 122 of the housing wall 110.

The material thickness d of the housing wall 110 is preferably smaller than 5 mm, in particular smaller than 4 mm, particularly preferably smaller than 3 mm.

Furthermore, the material thickness d of the housing wall 110 is preferably greater than 0.5 mm, in particular greater than 0.8 mm, particularly preferably greater than 1.2 mm.

The receiving structure 118 is produced on the housing element 102, for example, by a reshaping operation, for example an embossing operation, a bending operation, or a deep-drawing operation, being performed on the material of the housing wall 110 in the region of the housing wall 110 in which the through-opening 136 is to be arranged, in order to form the receiving structure 118 with the raised pressure compensation element abutment face 120.

Then, the passage opening 136 is separated out of the material of the housing wall 110, for example by drilling, milling, cutting, preferably by means of a laser, or by punching.

In principle, the through-opening 136 may also first be separated out of the material of the housing wall 110, for example by drilling, milling, cutting, preferably by means of a laser, or by punching, and then a reshaping operation may be performed on the remaining material of the housing wall, by which the receiving structure 118 with the raised pressure compensation element abutment face 120 relative to the outer face 116 of the base region 122 of the housing wall 110 is formed.

Such a reshaping operation may be, in particular, an embossing operation, a bending operation, or a deep-drawing operation.

This pressure compensation element 104 to be arranged on the receiving structure 118 comprises a pressure compensation element membrane 140.

The pressure compensation element membrane 140 may be configured, in particular, as a semipermeable membrane.

The outer contour of the pressure compensation element membrane 140 corresponds substantially to the outer contour of the pressure compensation element abutment face 120 of the receiving structure 118 of the housing element 102, such that the pressure compensation element membrane 140, in the mounted state of the pressure compensation element 104, substantially completely covers the pressure compensation element abutment face 120 and the through-opening 136 of the receiving structure 118.

In order to fix the pressure compensation element membrane 140 to the receiving structure 118, provision is preferably made that the pressure compensation element membrane 140 is connected to the receiving structure 118 by substance-to-substance bond, for example by adhesion.

As can best be seen in FIG. 4, the thickness of the pressure compensation element membrane 140 (including the adhesive layer between the pressure compensation element membrane 140 and the pressure compensation element abutment face 120, as the case may be) corresponds substantially to the height of the web 130 in the region of one of the discharge openings 130 over the pressure compensation element abutment face 120 or is less than this height, such that the peripheral face of the pressure compensation element membrane 140 is laterally covered and thus protected from environmental influences by the web 130 of the receiving structure 130.

The pressure compensation element 104 further comprises a protective cap 142, which covers the pressure compensation element membrane 140, such that a top side 144 of the pressure compensation element membrane 140, which faces away from the pressure compensation element abutment face 120, is also protected.

The protective cap 142 comprises at least one ventilation channel 146.

Such a ventilation channel 146 serves to aerate and/or to ventilate the pressure compensation element 104.

Provision is preferably made that such a ventilation channel 146 extends from an outside space-side fluid receiving space 148 up to an outlet opening 150 on the periphery of the protective cap 142.

The outside space-side fluid receiving space 148 is preferably arranged such that, in the mounted state of the pressure compensation element 104, it is located opposite the through-opening 136 of the receiving structure 118 of the housing element 102.

As can best be seen in FIG. 1 to 3 or 6, provision may be made that the protective cap 142 comprises a plurality of ventilation channels 146, which extend radially outwardly from the outside space-side fluid receiving space 148 up to the outer periphery of the protective cap 142.

The fluid receiving space 148 is preferably arranged substantially centrally on the protective cap 142.

The outlet openings 150 of the ventilation channels 146 of the protective cap 142 are preferably each arranged in alignment with a respective one of the discharge openings 132 of the web 130 of the receiving structure 118 of the housing element 102.

In particular, provision may thus be made that an outlet opening 150a of a first ventilation channel 146a is in alignment with the discharge opening 132a, which is arranged adjacent to the lowest point 126 of the pressure compensation element abutment face 120.

An outlet opening 150b of a second ventilation channel 146b is preferably in alignment with the discharge opening 132a, which is arranged adjacent to the highest point 128 of the pressure compensation element abutment face 120.

The outlet openings 150c and 150d of a third ventilation channel 146c and of a fourth ventilation channel 146d, respectively, are preferably in alignment with the discharge openings 132c and 132d, respectively, of the web 130, which are arranged along the periphery of the web 130 between the discharge openings 132a and 132b.

The ventilation channels 146 are provided, for example, by part of a disc-shaped protective cap preform being bent out of the plane of a top side 152 of the protective cap 142.

This reshaping operation may be a bending operation, an embossing operation, or a deep-drawing operation.

In the graphically depicted embodiment, the first ventilation channel 146a and the second ventilation channel 146b are in alignment with one another, such that they can be seen as one single rectilinear ventilation channel 146′ that extends from the outlet opening 150a up to the outlet opening 150b.

Furthermore, the third ventilation channel 146c and the fourth ventilation channel 146d are preferably in alignment with one another, such that these ventilation channels together can be seen as one rectilinear ventilation channel 146″ that extends from the outlet opening 150c up to the outlet opening 150d.

The two rectilinear ventilation channels 146′ and 146″ cross or intersect in the region of the outside space-side fluid receiving space 148 of the protective cap 142.

The protective cap 142 preferably consists of a metallic material, for example a steel material or an aluminum material.

An aluminum material may be an aluminum alloy or substantially pure aluminum.

The material thickness of the protective cap 142 is preferably smaller than the material thickness d of the base region 122 of the housing wall 110 of the housing element 102.

The material thickness of the protective cap 142 is preferably smaller than 1.0 mm, in particular smaller than 0.8 mm, particularly preferably smaller than 0.5 mm.

Furthermore, the material thickness of the protective cap 142 is preferably greater than 0.1 mm, in particular greater than 0.2 mm, particularly preferably greater than 0.3 mm.

In the operation of the pressure compensation element 104, a preferably gaseous fluid, for example air, can travel through the through-opening 136 of the receiving structure 118 of the housing element 102 from an inside space-side fluid receiving space 154, which is arranged on the inside space side 138 of the housing element 102, to the pressure compensation element membrane 140 and through the pressure compensation element membrane 140 into the outside space-side fluid receiving space 148 of the pressure compensation element 104.

From the outside space-side fluid receiving space 148, the fluid travels through the ventilation channels 146 in the protective cap 142 to the outlet openings 150 of the ventilation channels 146 and from there to the outside space side 114 of the housing element 102.

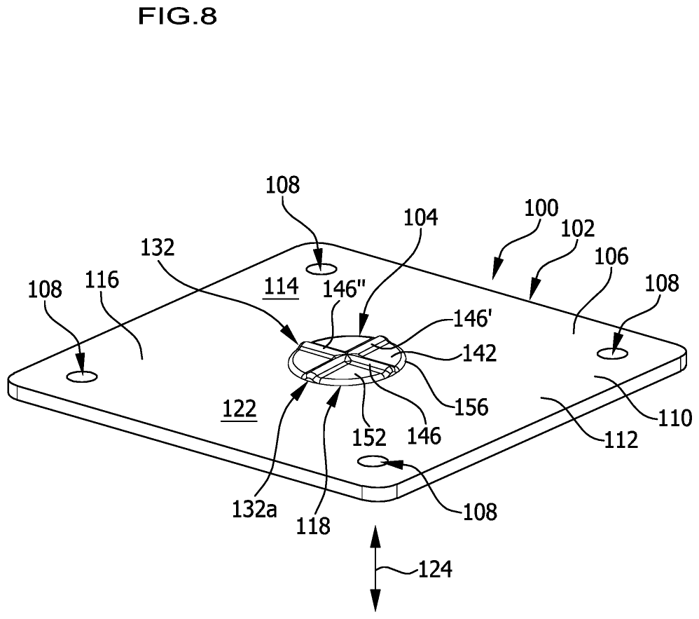

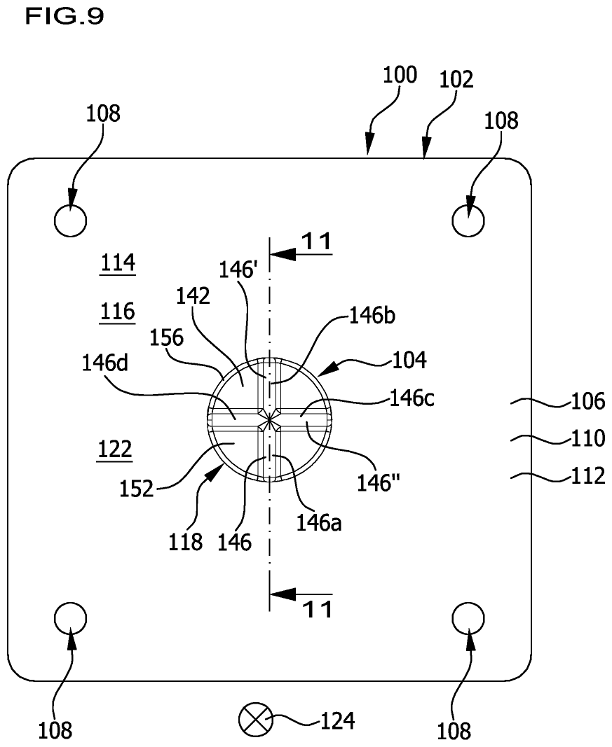

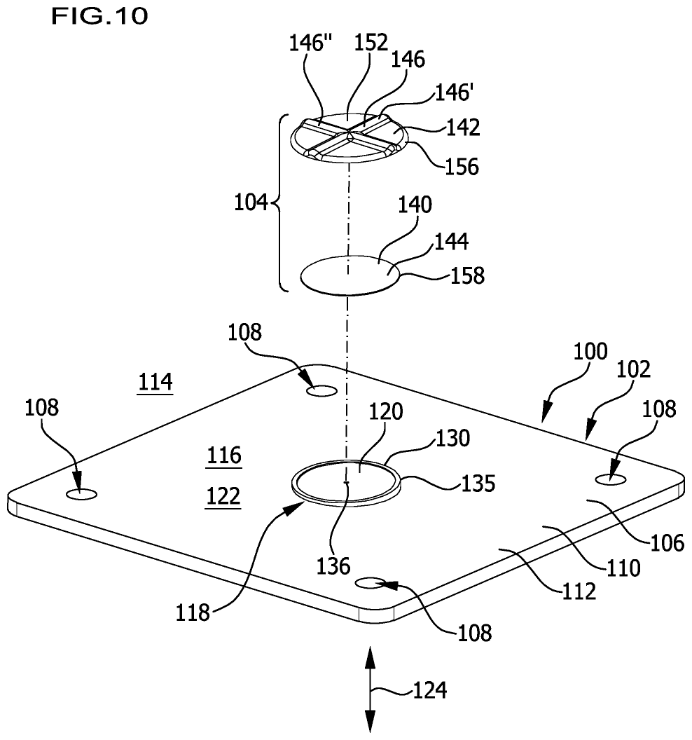

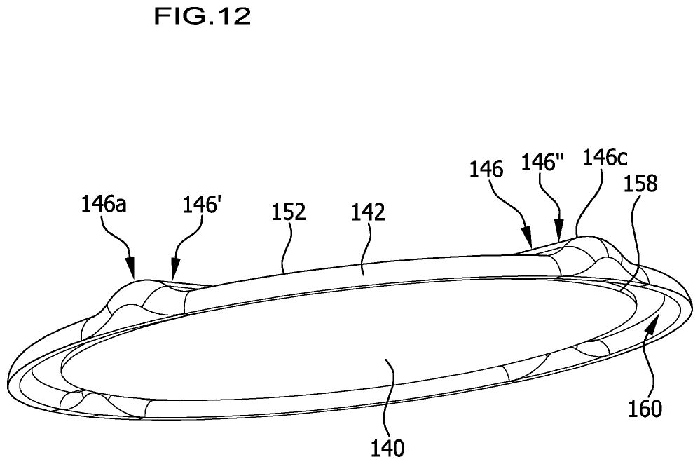

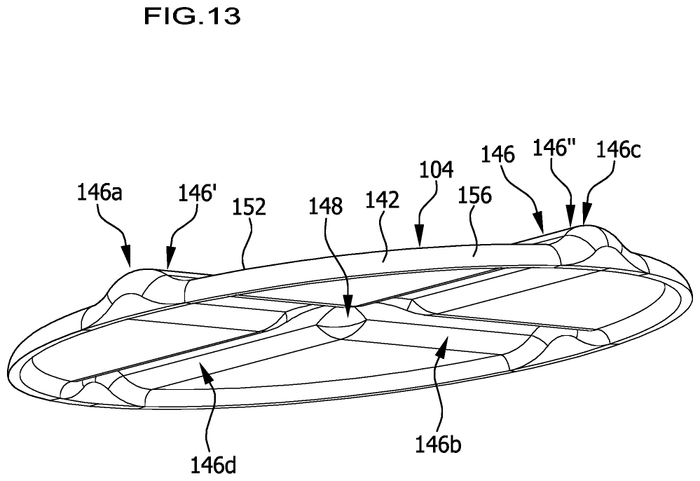

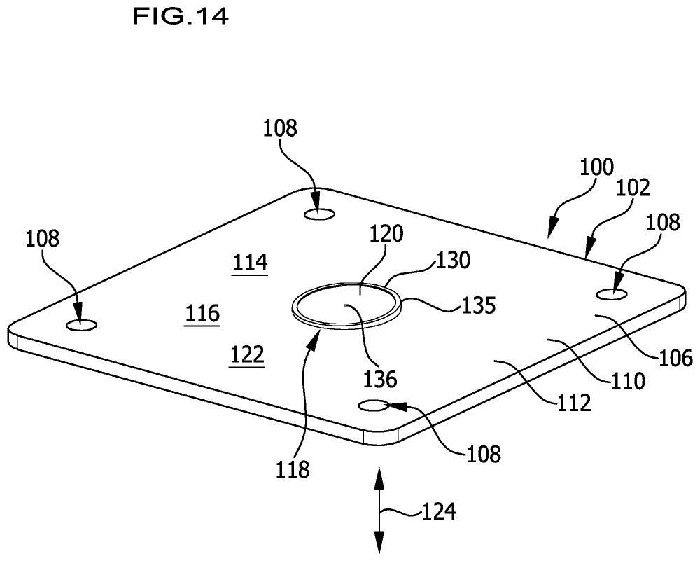

A second embodiment, depicted in FIGS. 8 to 14, of a combination 100 of a housing element 102 and a pressure compensation element 104 differs from the first embodiment depicted in FIGS. 1 to 7 in that the protective cap 142 comprises a collar 156, which laterally covers a peripheral rim 158 of the pressure compensation element membrane 140.

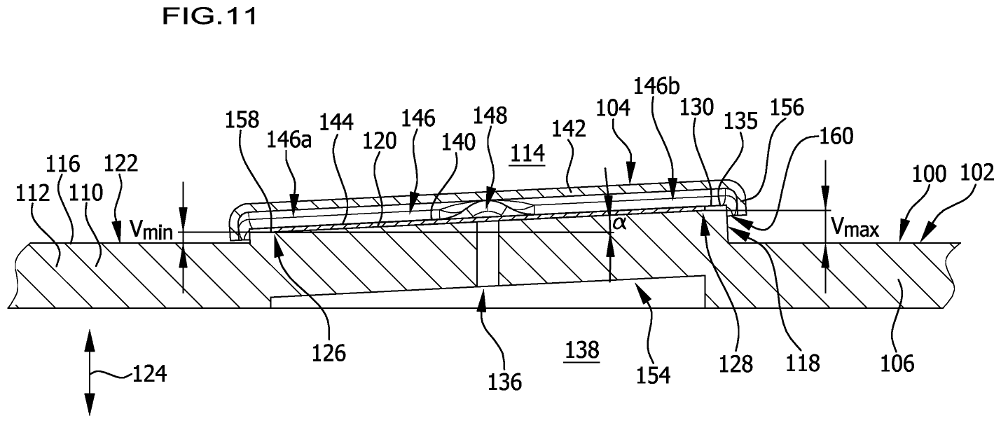

As can best be seen in the sectional view in FIG. 11, the collar 156 projects in the radial direction beyond the web 130 of the receiving structure 118 of the housing element 102, such that a gap 160 remains between the collar 156 of the protective cap 142 on the one hand and the web 130 of the receiving structure 118 of the housing element 102 on the other hand, through which gap 160 fluid can travel from the ventilation channels 146 of the protective cap 142 to the outside space side 114 of the housing element 102 or can travel from the outside space side 114 of the housing element 102 into the ventilation channels 146 of the protective cap 142 of the pressure compensation element 104.

In this embodiment, the web 130 of the receiving structure 118 of the housing element 102 preferably has the same height everywhere along its periphery, which substantially corresponds to the thickness of the pressure compensation element membrane 140 (including an adhesive layer between the pressure compensation element membrane 140 and the pressure compensation element abutment face 120, as the case may be).

In this embodiment, in principle, fluid arranged on the top side 144 of the pressure compensation element membrane 140 is therefore able to discharge onto the outer face 116 of the base region 122 of the housing wall 110 of the housing element 102 at any point of the web 130.

In all other respects, the second embodiment depicted in FIGS. 8 to 14 of a combination 100 of a housing element and a pressure compensation element 104 corresponds with respect to structure, function, and production method with the first embodiment depicted in FIGS. 1 to 7, to the preceding description of which reference is made in this regard.

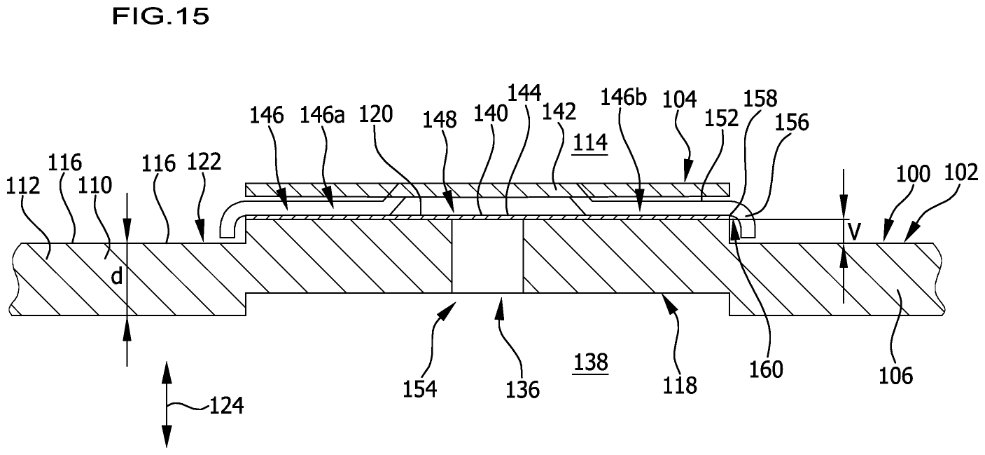

A third embodiment, depicted in FIG. 15, of a combination 100 of a housing element 102 and a pressure compensation element 104 differs from the second embodiment depicted in FIGS. 8 to 14 in that the pressure compensation element abutment face 120 of the receiving structure 118 is not inclined relative to the outer face 116 of the base region 122 of the housing wall 110 of the housing element 102, but instead is oriented substantially in parallel to the outer face 116.

In all other respects, the third embodiment depicted in FIG. 15 of a combination 100 a housing element 102 and a pressure compensation element 104 corresponds with respect to structure, function, and production method with the second embodiment depicted in FIGS. 8 to 14, to the preceding description of which reference is made in this regard.

In a variant of the third embodiment, provision could also be made that the protective cap 142 comprises no collar 156, but instead the ventilation channels 146 open at their respective outlet openings 150 on the outside space side 114 of the housing element 102.

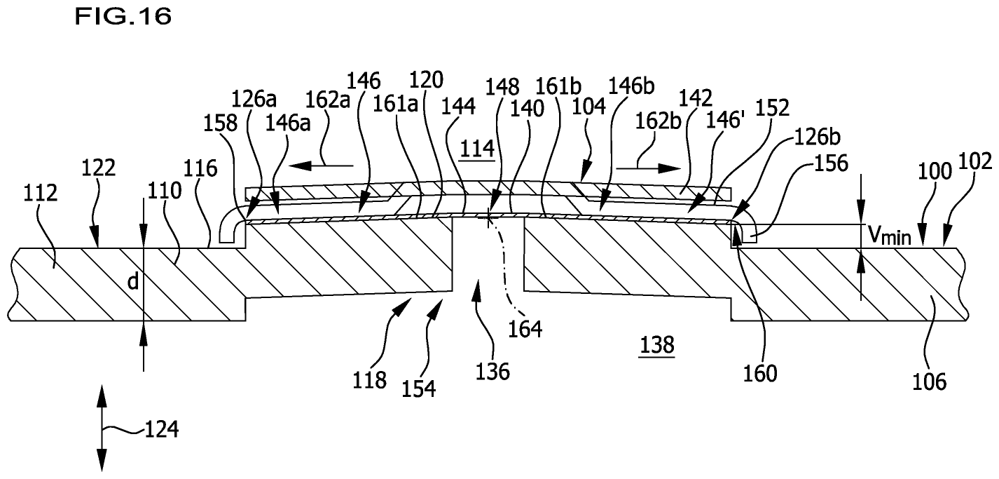

A fourth embodiment depicted in FIG. 16 of a combination 100 of a housing element 102 and a pressure compensation element 104 differs from the second embodiment depicted in FIGS. 8 to 14 in that the receiving structure 118 of the housing element 102 comprises not one single pressure compensation element abutment face 120 with a constant inclination relative to the outer face 116 of the base region 122 of the housing wall 110 of the housing element 102, but instead comprises two partial pressure compensation element abutment faces 161a and 161b inclined relative to the outer face 116 of the base region 122 of the housing wall 110, said partial pressure compensation element abutment faces 161a and 161b adjoining one another along a crest line 164 and sloping down from the crest line 164 along mutually different slope directions 162a and 162b, respectively.

The two partial pressure compensation element abutment faces 161a and 161b together form the pressure compensation element abutment face 120 of the receiving structure 118.

The crest line 164 preferably runs through the longitudinal central axis of the through-opening 136 of the receiving structure 118.

The partial pressure compensation element abutment face 161a depicted on the left in FIG. 16 slopes down from this crest line 164 along a slope direction 162b running from right to left in FIG. 16 toward a first lowest point 126a of the pressure compensation element abutment face 120.

Furthermore, the second partial pressure compensation element abutment face 161b slopes down from the crest line 164 along a slope direction 162b running from left to right in FIG. 16 toward a second lowest point 126b of the pressure compensation element abutment face 120.

In this embodiment, the crest line 164 preferably runs in parallel to the second rectilinear ventilation channel 146″ and substantially perpendicularly to the first rectilinear ventilation channel 146′.

In this embodiment, the web 130 protecting the peripheral rim of the pressure compensation element membrane 140 may be omitted.

In this embodiment, liquids located on the top side 144 of the pressure compensation element membrane 140 flow to substantially the same extent via the first lowest point 126a and via the second lowest point 126b of the pressure compensation element abutment face 120 onto the outer face 116 of the base region 122 of the housing wall 110 of the housing element 102 when the outer face 116 of the base region 122 of the housing wall 110 is oriented substantially horizontally.

In all other respects, the fourth embodiment depicted in FIG. 16 of a combination 100 of a housing element 102 and a pressure compensation element 104 corresponds with respect to structure, function, and production method with the second embodiment depicted in FIGS. 8 to 14, to the preceding description of which reference is made in this regard.

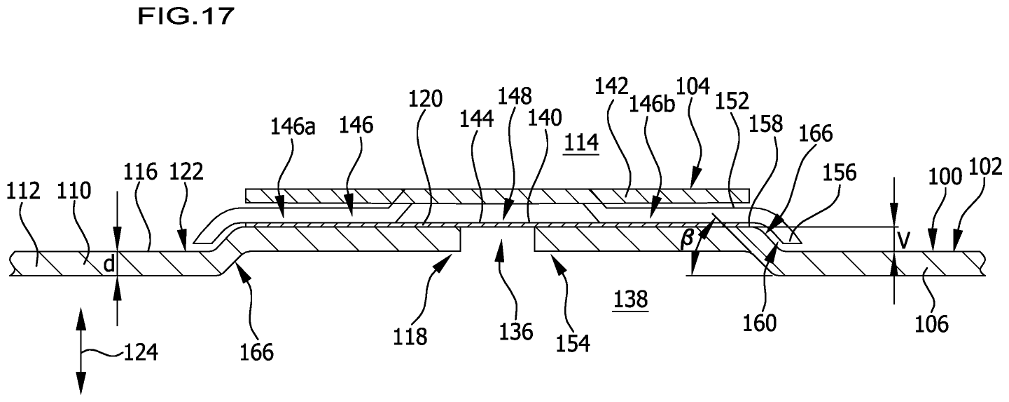

A fifth embodiment depicted in FIG. 17 of a combination 100 of a housing element 102 and a pressure compensation element 104 differs from the third embodiment depicted in FIG. 15 in that the minimum offset Vₘᵢₙ of the pressure compensation element abutment face 120 relative to the outer face 116 of the base region 122 of the housing wall 110 of the housing element 102 along the thickness direction 124 of the base region 122 of the housing wall 110 is equal to or greater than the material thickness d of the housing wall 110 in the base region 122.

In this embodiment, the receiving structure 118 of the housing element 102 transitions into the base region 122 of the housing wall 110 not in a step, but along a slope 166.

The angle of inclination β of the slope 166 relative to the outer face 116 of the base region 122 of the housing wall 110 is preferably more than 20°, in particular more than 30°, particularly preferably more than 40°.

Furthermore, the angle of inclination β of the slope 166 relative to the outer face 116 of the base region 122 of the housing wall 110 is preferably less than 70°, in particular less than 60°, particularly preferably less than 50°.

The reshaping operation by means of which the receiving structure 118 of the housing element 102 is produced in this embodiment is preferably a bending operation or a deep-drawing operation.

In all other respects, the fifth embodiment depicted in FIG. 17 of a combination 100 of a housing element 102 and a pressure compensation element 104 corresponds with respect to structure, function, and production method with the third embodiment depicted in FIG. 15, to the preceding description of which reference is made in this regard.

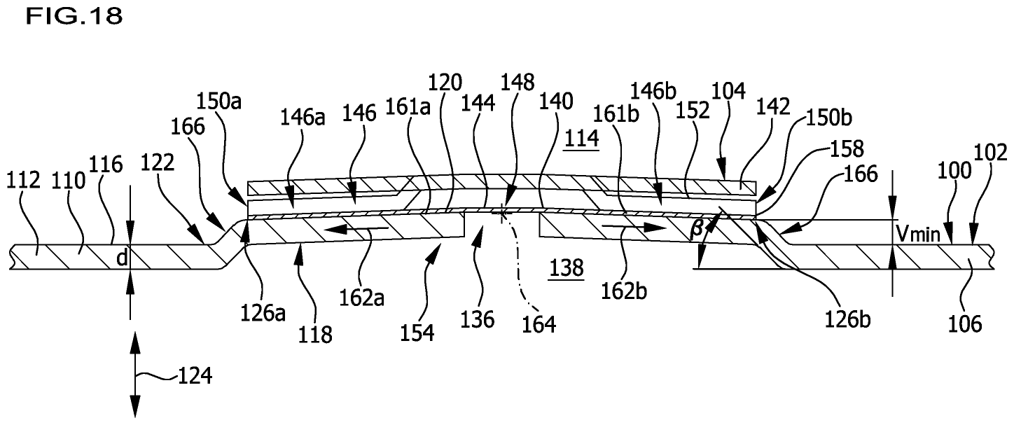

A sixth embodiment depicted in FIG. 18 of a combination of a housing element 102 and a pressure compensation element 104 differs from the fourth embodiment depicted in FIG. 16 in that the minimum offset Vₘᵢₙ of the partial pressure compensation element abutment faces 161a and 161b relative to the outer face 116 of the base region 122 of the housing wall 110 of the housing element 102 along the thickness direction 124 of the base region 122 of the housing wall 110 is equal to or greater than the material thickness d of the housing wall 110 in the base region 122.

In this embodiment, the receiving structure 118 of the housing element 102 therefore transitions into the base region 122 of the housing wall 110 not in a step, but along a slope 166.

The angle of inclination β of the slope 166 relative to the outer face 116 of the base region 122 of the housing wall 110 is preferably more than 20°, in particular more than 30°, particularly preferably more than 40°.

Furthermore, the angle of inclination β of the slope 166 relative to the outer face 116 of the base region 122 of the housing wall 110 is preferably less than 70°, in particular less than 60°, particularly preferably less than 50°.

The reshaping operation by means of which the receiving structure 118 of the housing element 102 is produced in this embodiment is preferably a bending operation or a deep-drawing operation.

Furthermore, in the sixth embodiment depicted in FIG. 18, provision may be made that the protective cap 142 of the pressure compensation element 104 comprises no collar 156, which laterally covers a peripheral rim 158 of the pressure compensation element membrane 140.

Instead, provision may be made that the ventilation channels 146 of the protective cap 142 open at their peripheral outlet openings 150 directly on the outside space side 114 of the housing element 102.

In all other respects, the sixth embodiment depicted in FIG. 18 of a combination 100 of a housing element 102 and a pressure compensation element 104 corresponds with respect to structure, function, and production method with the fourth embodiment depicted in FIG. 16, to the preceding description of which reference is made in this regard.

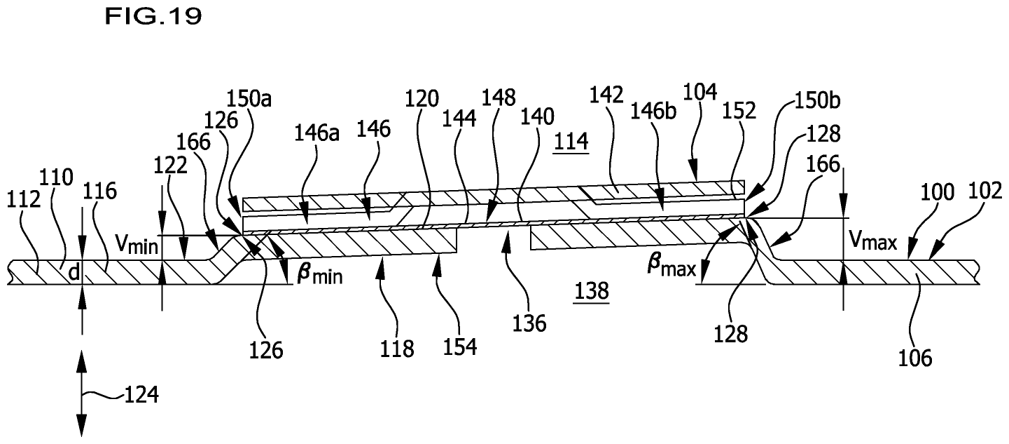

A seventh embodiment depicted in FIG. 19 of a combination 100 of a housing element 102 and a pressure compensation element 104 differs from the first embodiment depicted in FIGS. 1 to 7 in that the minimum offset Vₘᵢₙ of the pressure compensation element abutment face 120 relative to the outer face 116 of the base region 122 of the housing wall 110 of the housing element 102 along the thickness direction 124 of the base region 122 of the housing wall 110 is equal to or greater than the material thickness d of the housing wall 110 in the base region 122.

In this embodiment, the receiving structure 118 of the housing element 102 therefore transitions into the base region 122 of the housing wall 110 not in a step, but along a slope 166.

In this embodiment, due to the inclination of the pressure compensation element abutment face 120 relative to the outer face 116 of the base region 122 of the housing wall 110, the angle of inclination β of the slope 166 relative to the outer face 116 of the base region 122 of the housing wall 110 may vary along the periphery of the receiving structure 118.

The angle of inclination β preferably has its smallest value βₘᵢₙ adjacent to the lowest point 126 of the pressure compensation element abutment face 120 and its greatest value βₘₐₓ adjacent to the highest point 128 of the pressure compensation element abutment face 120.

The smallest angle of inclination β of the slope 166 relative to the outer face 116 of the base region 122 of the housing wall 110 is preferably more than 20°, in particular more than 30°, particularly preferably more than 40°.

Furthermore, the smallest angle of inclination βₘᵢₙ of the slope 166 relative to the outer face 116 of the base region 122 of the housing wall 110 is preferably less than 70°, in particular less than 60°, particularly preferably less than 50°.

The greatest angle of inclination βₘₐₓ of the slope 166 relative to the outer face 116 of the base region 122 of the housing wall 110 is preferably more than 40°, in particular more than 50°, particularly preferably more than 60°.

Furthermore, the greatest angle of inclination βₘₐₓ of the slope 166 relative to the outer face 116 of the base region 122 of the housing wall 110 is preferably less than 85°, in particular less than 80°, particularly preferably less than 70°.

The reshaping operation by means of which the receiving structure 118 of the housing element 102 is produced in this embodiment is preferably a bending operation or a deep-drawing operation.

In principle, the protective cap 142 may comprise a collar 156 in the seventh embodiment depicted in FIG. 19, too, which laterally covers a peripheral rim 158 of the pressure compensation element membrane 140.

In all other respects, the seventh embodiment depicted in FIG. 19 of a combination 100 of a housing element 102 and a pressure compensation element 104 corresponds with respect to structure, function, and production method with the first embodiment depicted in FIGS. 1 to 7, to the preceding description of which reference is made in this regard.

1. A housing element,
comprising a housing wall and a receiving structure for a pressure compensation element,
wherein the receiving structure comprises a through-opening for the passage of a gas,
wherein the receiving structure comprises at least one pressure compensation element abutment face that is raised, at least in sections, relative to an outer face of a base region of the housing wall.

2. The housing element in accordance with claim 1, wherein the receiving structure comprises a raised web extending around the pressure compensation element abutment face.

3. The housing element in accordance with claim 2, wherein the web is provided with at least one discharge opening.

4. The housing element in accordance with claim 1, wherein the pressure compensation element abutment face is inclined, at least in sections, relative to the outer face of the base region of the housing wall.

5. The housing element in accordance with claim 1, wherein the receiving structure comprises at least two partial pressure compensation element abutment faces that are inclined relative to the outer face of the base region of the housing wall and have mutually different slope directions.

6. The housing element in accordance with claim 5, wherein at least two of the partial pressure compensation element abutment faces of the receiving structure adjoin one another along a crest line and slope down from the crest line along mutually different slope directions.

7. The housing element in accordance with claim 1, wherein the receiving structure is formed in one piece with the housing wall.

8. The housing element in accordance with claim 1, wherein the receiving structure is formed by reshaping part of the housing wall.

9. A combination of a pressure compensation element and a housing element, said housing element comprising a housing wall and a receiving structure for a pressure compensation element,
wherein the receiving structure comprises a through-opening for the passage of a gas,
wherein the receiving structure comprises at least one pressure compensation element abutment face that is raised, at least in sections, relative to an outer face of a base region of the housing wall,
wherein the pressure compensation element comprises a pressure compensation element membrane that is arranged on the pressure compensation element abutment face of the housing element.

10. The combination in accordance with claim 9, wherein the pressure compensation element membrane is adhesively bonded to the pressure compensation element abutment face.

11. The combination in accordance with claim 9, wherein the pressure compensation element comprises a protective cap, which covers the pressure compensation element membrane.

12. The combination in accordance with claim 11, wherein the protective cap comprises at least one ventilation channel.

13. The combination in accordance with claim 12, wherein the protective cap comprises two intersecting ventilation channels.

14. The combination in accordance with claim 11, wherein the protective cap comprises a collar, which laterally covers a rim of the pressure compensation element membrane.

15. A method for producing a combination of a housing element and a pressure compensation element,
comprising the following:
reshaping a housing wall of the housing element for forming a receiving structure;
producing a through-opening in the region of the receiving structure, wherein the receiving structure comprises at least one pressure compensation element abutment face that is raised, at least in sections, relative to an outer face of a base region of the housing wall;
arranging a pressure compensation element membrane of the pressure compensation element on the at least one pressure compensation element abutment face.

16. The method in accordance with claim 15, wherein a protective cap is arranged on the side of the pressure compensation element membrane of the pressure compensation element that faces away from the receiving structure of the housing element.
